(19) United States
(12) Patent Application Publication
(10) Pub. No.: US 2014/0057045 A1
(43) Pub. Date: Feb. 27, 2014

(54) METHOD OF CHANGING THE OPTICAL PROPERTIES OF HIGH RESOLUTION CONDUCTING PATTERNS

(71) Applicant: UNIPIXEL DISPLAYS, INC., The Woodlands, TX (US)

(72) Inventors: Ed S. Ramakrishnan, The Woodlands, TX (US); Danliang Jin, The Woodlands, TX (US)

(73) Assignee: UNIPIXEL DISPLAYS, INC., The Woodlands, TX (US)

(21) Appl. No.: 13/980,363

(22) PCT Filed: Oct. 25, 2012
(86) PCT No.: PCT/US2012/061926

§ 371 Date: Jul. 18, 2013

Related U.S. Application Data
(60) Provisional application No. 61/551,175, filed on Oct. 25, 2011.

(51) Int. Cl. H05K 3/18; H05K 3/12

(52) U.S. Cl. CPC H05K 3/182; H05K 3/12
USPC 427/97.4

(57) ABSTRACT

The disclosure disclosed herein is a method for altering the optical properties of high resolution printed conducting patterns by initiating a chemical reaction to a passivating layer on the patterns with optical properties differing from the untreated material. The electrical properties are maintained after this reacted, passivating, layer is formed.

### CROSS-REFERENCE TO RELATED APPLICATION

The present application claims priority to U.S. Provisional Patent Application No. 61/551,175, filed on Oct. 25, 2011 (Attorney Docket No. 2911-02900); which is hereby incorporated herein by reference.

### BACKGROUND

Touch sensitive displays may be used in televisions, kiosks, and personal computing devices including personal computers, smart phones, portable electronic devices, personal digital assistants (PDAs), and tablets. The touch sensitive displays may include touch sensors that have a set of non-transparent conductive lines disposed in a grid pattern. While very thin, such conductive patterns may be visible to the user of the touch sensitive display which may be bothersome to the user. While the user may not be able to see the lines because the lines are microscopic, there may be glare and reflection on the display because of these conductive patterns.

### SUMMARY

In an embodiment, a method of changing the optical properties of a high resolution conductive pattern comprising: printing a first microscopic pattern on a first side of a first substrate using an ink comprising a plating catalyst; curing the substrate; printing a second microscopic pattern using the ink; plating the substrate, wherein plating the substrate comprising electroless plating, to form a high resolution conductive pattern (HRCP) on the substrate; disposing, on the substrate, a reactant, to form a reacting pattern comprising a reacted layer, wherein the reacted layer thickness is between 25 nm-5000 nm; and rinsing the substrate.

In an alternate embodiment, a method of changing the optical properties of a high resolution conductive pattern comprising: printing a first microscopic pattern on a first side of a substrate using an ink comprising a plating catalyst; curing the first substrate; printing a second microscopic pattern using the ink; and plating the substrate, wherein plating the substrate comprising electroless plating, to form a high resolution conductive pattern (HRCP) on the substrate. The embodiment further comprising disposing, on the substrate, a reactant, to form a reacting pattern comprising a reacted layer, wherein the reacted layer thickness is between 25 nm-5000 nm, and wherein the reactant comprises SeO₂, CuSO₄, and phosphoric acid; and rinsing the substrate in one of in one of isopropyl alcohol and deionized water.

### BRIEF DESCRIPTION OF THE DRAWINGS

For a detailed description of exemplary embodiments of the invention, reference will now be made to the accompanying drawings in which:

FIGS. 1A-1C is an illustration of an embodiment of a seven step method for changing the optical properties of a high resolution conducting pattern (HRCP).

FIG. 2 is an illustration of an embodiment of a three step method of changing the optical properties of an HRCP.

FIG. 3 is an illustration of an embodiment of a four step method of changing the optical properties of an HRCP.

FIG. 4 is an illustration of an embodiment of a three step method of changing the optical properties of an HRCP.

FIG. 5 is an embodiment of a three step method of a colorization method for an HRCP.

FIG. 6 is an illustration of a conductive pattern on a substrate.

FIG. 7 is an illustration of a conductive pattern with modified optical properties on a substrate.

FIGS. 8A-8B are illustrations of cross-sections of patterned lines of two embodiments of HRCPs with modified optical properties.

FIG. 10 is an illustration of an embodiment of a method for manufacturing a colorized high resolution conductive pattern (CHRCP).

FIG. 11 shows a diagram of a method for batch colorizing high resolution conducting patterns.

FIG. 12 shows formulas for triazole compounds.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Capacitive and resistive touch sensors may be used in electronic devices with touch-sensitive features. These electronic devices may include display devices such a computing device, a computer display, or a portable media player. Display devices may include televisions, monitors and projectors that may be adapted to displays images, including text, graphics, video images, still images or presentations. The image devices that may be used for these display devices may include cathode ray tubes (CRTs), projectors, flat panel liquid crystal displays (LCDs), LED systems, OLED systems, plasma systems, electroluminescent displays (ELDs), field emissive displays (FEDs). As the popularity of touch screen devices increases, manufacturers may seek to employee methods of manufacture that will preserve quality while reducing the cost of manufacture and simplify the manufacturing process. The optical performance of touch screens may be improved by reducing optical interference, for example the moire effect that is generated by regular conductive patterns formed by photolithographic processes. Systems and methods of fabricating flexible and optically compliant touch sensors in a high-volume roll-to-roll manufacturing process where micro electrically conductive features can be created in a single pass are disclosed herein.

Disclosed herein are embodiments of a system and a method to fabricate a flexible touch sensor (FTS) circuit by, for example, a roll-to-roll manufacturing process. A plurality of master plates may be fabricated using thermal imaging of selected designs in order print high resolution conductive lines on a substrate. A first pattern may be printed using a first roll on a first side of the substrate, and a second pattern may be printed using a second roll on a second side of the substrate. Electroless plating may be used during the plating process. While electroless plating may be more time consuming than other methods, it may be better for small, complicated, or intricate geometries. The FTS may comprise a plurality of thin flexible electrodes in communication with a dielectric layer. An extended tail comprising electrical leads may be attached to the electrodes and there may be an electrical connector in electrical communication with the leads. The roll-to-roll process refers to the fact that the flexible substrate is loaded on to a first roll, which may also be referred to as an unwinding roll, to feed it into the system where the fabrication process occurs, and then unloaded on to a second roll, which may also be referred to as a winding roll, when the process is complete.

Touch sensors may be manufactured using a thin flexible substrate transferred via a known roll-to-roll handling method. The substrates is transferred into a washing system that may comprise a process such as plasma cleaning, elastomeric cleaning, ultrasonic cleaning process, etc. The washing cycle may be followed by thin film deposition in physical or chemical vapor deposition vacuum chamber. In this thin film deposition step, which may be referred to as a printing step, a transparent conductive material, such as Indium Tin Oxide (ITO), is deposited on at least one surface of the substrate. In some embodiments, suitable materials for the conductive lines may include copper (Cu), silver (Ag), gold (Au), nickel (Ni), tin (Sn) and Palladium (Pd) among others. Depending on the resistivity of the materials used for the circuit, it may have different response times and power requirements. The deposited layer of conductive material may have a resistance in a range of 0.005 micro-ohms to 500 ohms per square, a physical thickness of 500 angstroms or less, and a width of 25 microns or more. In some embodiments, the printed substrate may have anti-glare coating or diffuser surface coating applied by spray deposition or wet chemical deposition. The substrate may be cured by, for example, heating by infrared heater, an ultraviolet heater convection heater or the like. This process may be repeated and several steps of lamination, etching, printing and assembly may be needed to complete the touch sensor circuit.

The pattern printed may be a high resolution conductive pattern comprising a plurality of lines. In some embodiments, these lines may be microscopic in size. The difficulty of printing a pattern may increase as the line size decreases and the complexity of the pattern geometry increases. The ink used to print features of varying sizes and geometries may also vary, some ink compositions may be more appropriate to larger, simple features and some more appropriate for smaller, more intricate geometries.

In an embodiment, there may be multiple printing stations used to form a pattern. These stations may be limited by the amount of ink that can be transferred on an anilox roll. In some embodiments, there may be dedicated stations to print certain features that may run across multiple product lines or applications, these dedicated stations may, in some cases, use the same ink for every printing job or may be standard features common to several products or product lines which can then be run in series without having to change out the roll. The cell volume of an anilox roll or rolls used in the transfer process, which may vary from 0.5-30 BCM (billion cubic microns) in some embodiments and 9-20 BCM in others, may depend on the type of ink being transferred. The type of ink used to print all or part of a pattern may depend on several factors, including the cross-sectional shape of the lines, line thickness, line width, line length, line connectivity, and overall pattern geometry. In addition to the printing process, at least one curing process may be performed on a printed substrate in order to achieve the desired feature height.

In some cases, the optical properties of the conductive material deposited during the plating process may be changed by further processing. Changing the optical properties of a reflective line, which may also be referred to as colorizing or blackening, may enhance visibility and usability of a display because darker lines absorb more of the light spectrum, thereby making the HRCPs less visible to the user of the display. The optical properties may be changed, for example, by forming an oxide layer on the HRCP lines. An oxide layer, which may also be referred to as a treated layer or a reacted layer, may be formed by the initiation and cessation of a chemical reaction. This chemical reaction may be initiated by a selenium compound, a sulphate compound, or a triazole compound. The mechanism used to apply the reactant may be a spray or a dip process, either of which may be used with the above compounds. The reactant is applied and the reaction is allowed to continue until it is stopped by a rinsing process to remove the reactant. It is appreciated that a process such as disclosed herein that produces a pattern where the optical transmission measured between 400-700 nm shows no difference, and as such no decrease, after the blackening process. For example, a grid pattern 15 μm by 15 μm and a spacing of 300 μm may exhibit about 88% transmission, which is comparable to or better than conventional touch panel technologies discussed above that may use indium tin oxide (ITO).

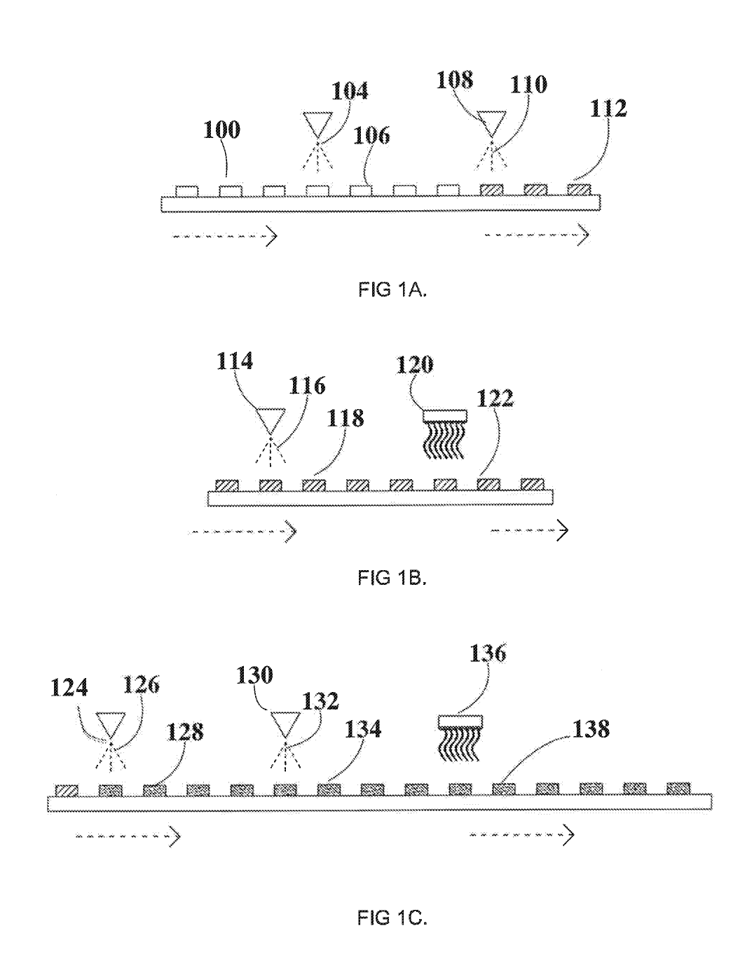

FIGS. 1A-1C are an embodiment of a method of modifying the optical properties of a high resolution conducting pattern (HRCP). A High Resolution Conducting Pattern (HRCP) may be any conductive material patterned on a non-conductive substrate where the conductive material is less than 50 μm wide along the printing plane of the substrate. The HRCP may comprise a plurality of lines the cross sections of which may be rectangles as in FIG. 1, or, for example, shapes such as squares, half-circles, trapezoids, triangles, etc.

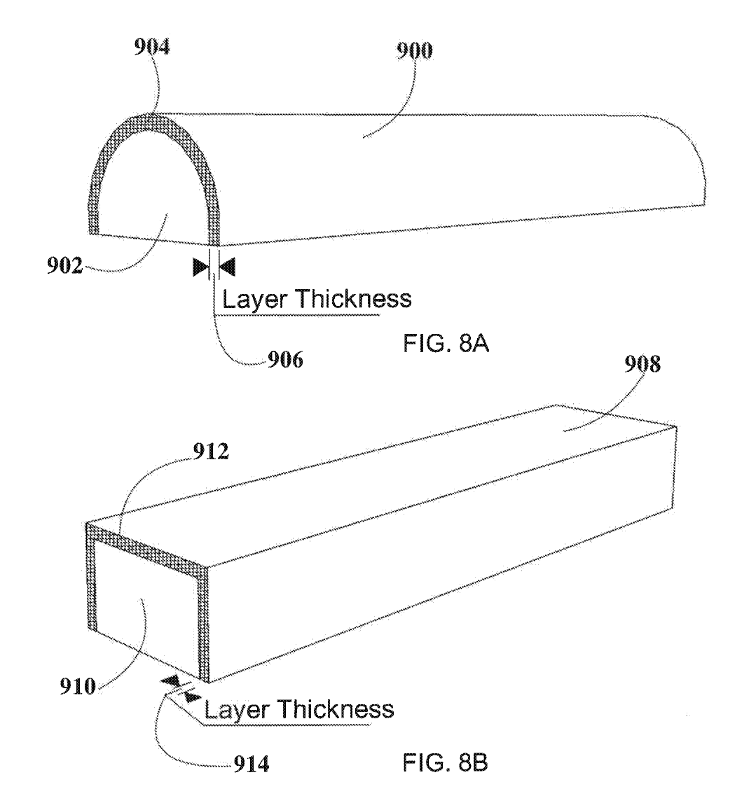

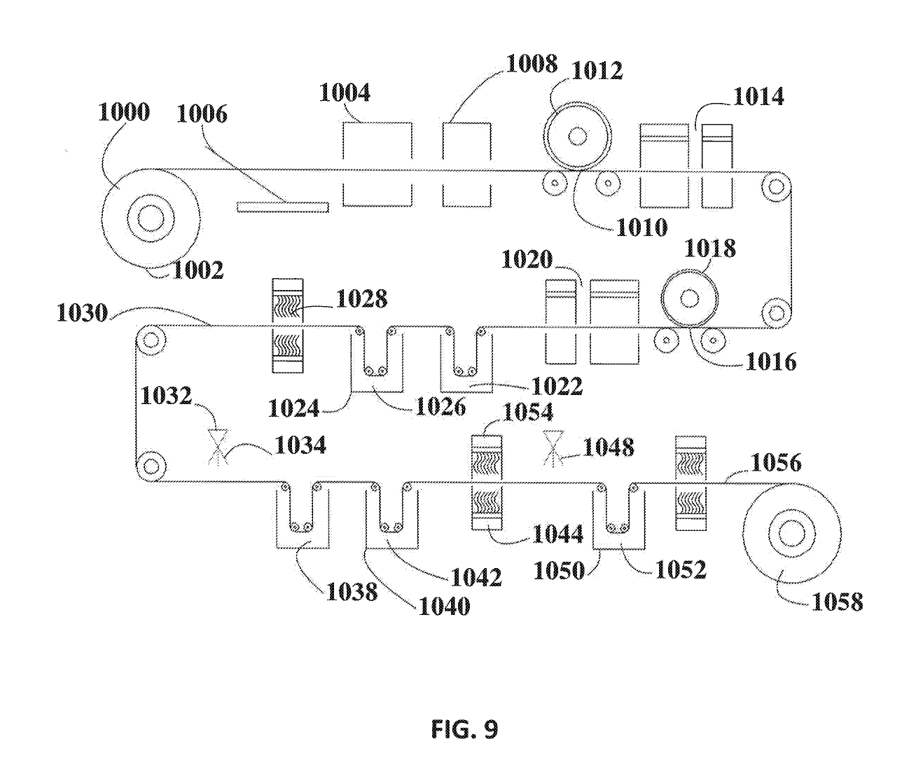

In FIG. 1A, a mask 104 is applied onto portions of high resolution conducting pattern (HRCP) 100, forming masked pattern 106. The term “mask” may be used to refer to any material applied to one or more areas of a material to reduce or inhibit the material's ability to interact with a reactant 110. For a given material, the reactant 110 may be any chemical that interacts with the HRCP on the substrate. The reactant 110 may be applied to masked pattern 106, forming reacting pattern 112, specifically, a reacted layer on the surface of the substrate of pattern 100, the reacted layer may be as illustrated in FIGS. 8A-8B. The amount of reactant applied to initiate a reaction with the HRCP may depend upon at least one of the type of reactant, the type of conductive material used to form the HRCP, and the geometry of the HRCP. The reaction completeness for a given material and a corresponding reactant may be the degree of completion of a chemical reaction between a material and a reactant. The degree of completion may be measured by properties such as layer thickness as discussed below in FIGS. 8A, 8B, and Table 1 or resistivity as discussed below in Table 1. The reacted pattern retains its conductivity and, preferably, the conductivity should be within 7% of pure copper, otherwise the reaction may cause the coating to become insulating.

Preferably, mask 104 is a photoresist mask such as a commercially available photoresist material in the AZ® nLOF™ 2000 series, the reactant 110 is a commercial product such as Novacan Black Patina, and the remover 126 is acetone. In another embodiment, reactant 110 is 3-10% Copper Sulfate (CuSO₄) by weight, and the remover at remover station 126 is Dimethyl sulfoxide. In another embodiment, reactant 110 is an aqueous solution of 7-15% Nitric Acid (HNO₃), 0.5-3%, Selenium Dioxide (SeO₂). In this example, the nitric acid in the solution cleans the Cu surface of any oxide growth, the selenium dioxide in the aqueous solution forms Selenous Acid (H2SeO3) and Cu2Se forms as in the following reaction:

4Cu+H₂SeO₃+4H=2Cu++Cu₂Se+3H2O.

In one example, the reactant is diluted with deionized (DI) water to control the reaction rate. The dilution may be by a ratio of 1 part reactant to 3 parts water (1:3). Alternatively, ratios of reactant:water may be 2:7, 1:4, 1:5, 1:7, and 1:9. The reaction may proceed from 10 seconds-60 seconds. In another example, the reactant is EPI-311, manufactured by Electrochemical Products Inc. (EPI). In another example, a telluride-based reactant such as sodium telluride may be used to produce a Cu-telluride reacted layer on the HRCO.

At FIG. 1B, a first rinse station 114 rinses the reacted pattern 112 using rinsing fluid 116 which forms a rinsed masked pattern 118. The rinsed masked pattern is dried at drying station 120 to remove rinsing fluid 116 from the rinsed masked pattern 118 to form a dry masked pattern 122. A rinse at first rinse station 124 may be performed using any fluid capable of dissolving a reactant or remover. The rinse may be performed with, for example, deionized water or isopropyl-alcohol (IPA). The substrate may be dried at drying station 120 by any method by which a reactant, remover, or rinsing liquid may be removed from a material, for example, air knifes, heated air, and squeegees.

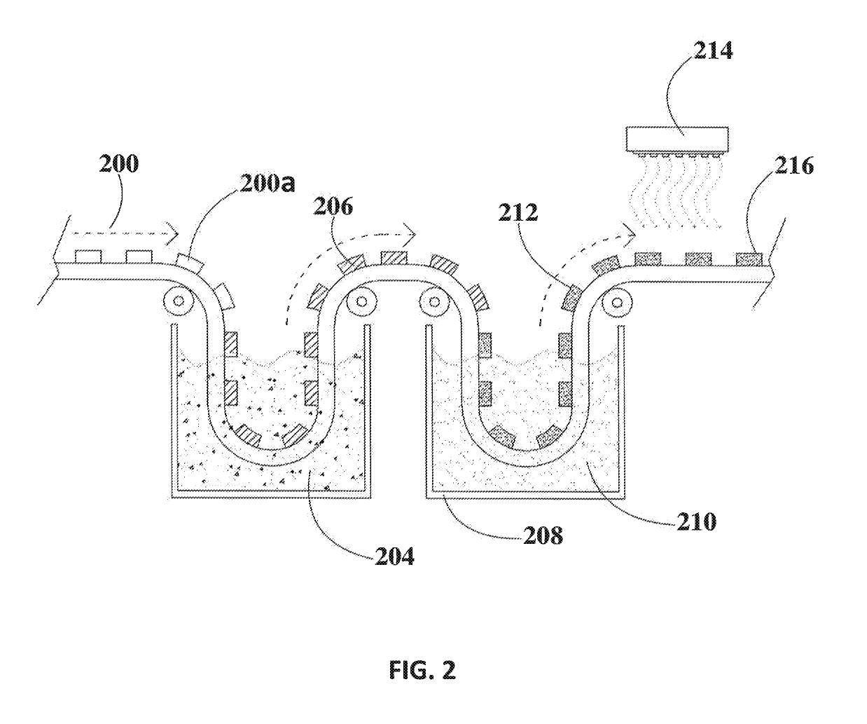

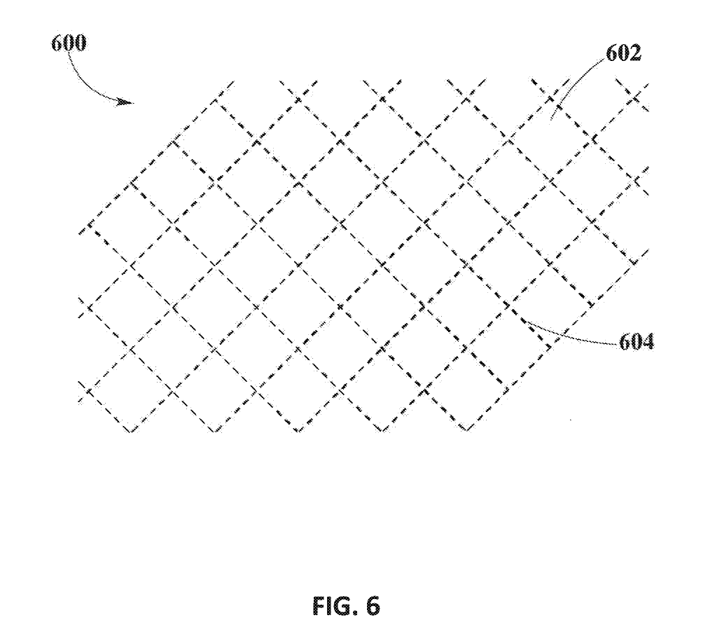

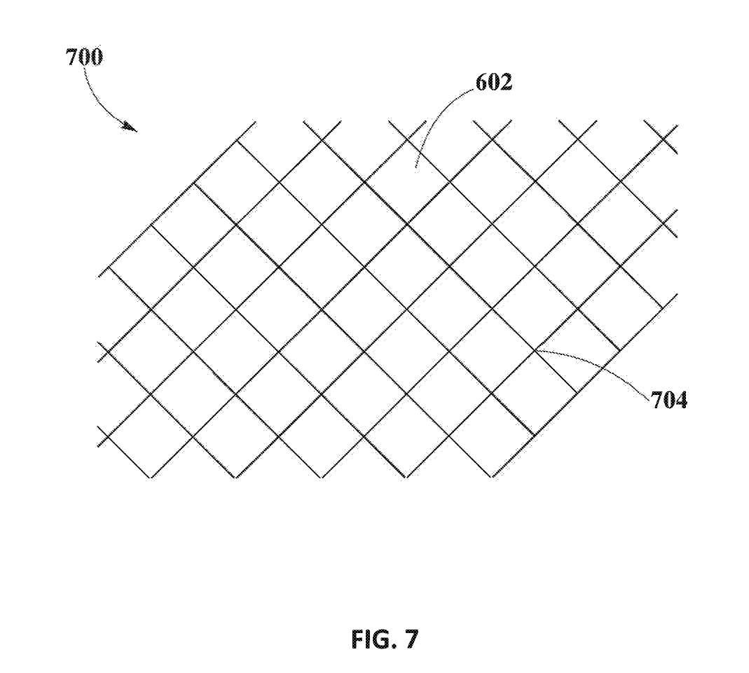

In FIG. 1C, in some embodiments where a mask 104 was applied at masking station 102, a remover may be applied at remover station 126 to remove the mask 104, resulting in reacted, unmasked pattern 128. A remover for a given reactant 110 may be any chemical that interacts with the material to remove it from another material which stops the reaction that forms the pattern 128. It is appreciated that while FIGS. 1A-1C show a change in the pattern when the reactant 110 is applied and when reactant 110 is removed at rinse station 124, this is done for illustrative purposes to show the initiation of the reaction when reactant 110 is applied and that the reaction may be stopped when the rinse is applied at rinse station 124, and not to actually show the pattern blackening as illustrated in the comparison of FIGS. 6 and 7, discussed below. It is also appreciated that the same type of shading scheme was used in FIGS. 2-5.

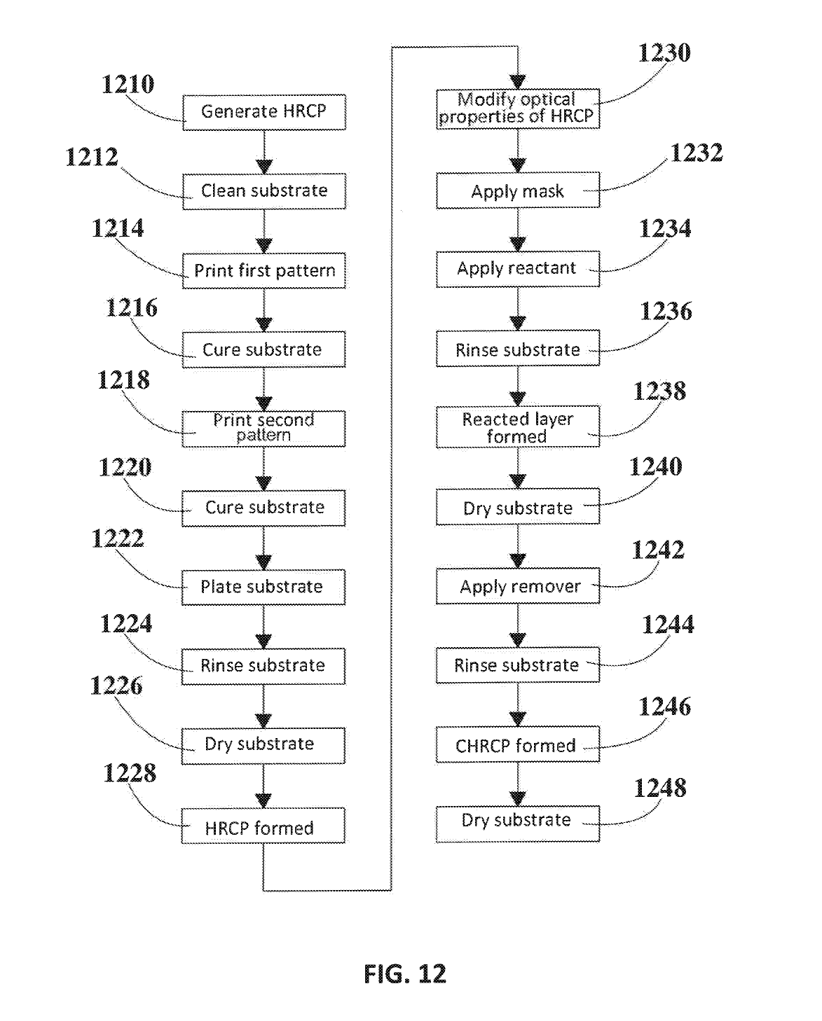

A rinse station 130 may then be used to apply a first rinsing fluid 132, forming rinsed colorized pattern 134. The rinsed colorized pattern 134 is dried 136 to remove a second rinsing fluid 132 from rinsed colorized pattern 134, forming colorized high resolution conducting pattern (CHRCP) 138. In an embodiment, spin coating apparatuses may be used to apply mask 104, reactant 110, and remover at remover station 126. The first rinse 114 and the second rinse station 130 may be applied as sprays that utilize Isopropyl Alcohol as the first rinsing fluid 116 and deionized water as the second rinsing fluid 132. In this example, the reactant 110 includes a triazole compound from, for example, a triazole as described in FIG. 12 below such as 1,2,3-Triazole 1200. Preferably, NH— Group 1208 in 1,2,3-Triazole 1200 is adsorbed to the exposed copper in reacting pattern 112. This reaction may proceed as described by the formula below:

Cu(s)+TA(triazole)=Cu:TAH(ads)+H+(aq)

In the presence of oxidants, or by anodic polarization, oxidation follows as in the following reaction:

Cu:TAH(ads)=Cu(I)TA(s)+H+(aq)+e-

As a product of this reaction, a protective layer of Cu(I)TA(s) is formed on reacting pattern 112. The thickness of this layer (not pictured) may depend on the concentration of triazole used in the reaction and may have an effect on the optical properties of reacting pattern 112. For a given material, the term “optical properties” may refer to any material characteristics derived from the way the material interacts with electromagnetic waves in the visible light spectrum, including but not limited to gloss and color.

The copper in reacting pattern 112 may form a type of bond with NH— Group 1208 in 1,2,3-Triazole 1200. The bonding that may occur may refer to any method by which at least one portion of a high resolution conducting pattern may be attached to another material. Additionally, the hydrogen resulting from the reaction may be adsorbed into the copper. Preferably, NH— Group 1208 in other 1,2,3-Triazole 1200 molecules become associated with tertiary nitrogens in the 1,2,3-Triazole 1200 molecules attached to the copper surface. In this example, alkyls are present in reactant 110, and as such the aforementioned hydrogen bonding is aided by the formation of micelles of said alkyls, forming an additional protective layer comprising alkyltriazoles with a structure similar to Alkyltriazole 1202 or Alkyltriazole 1204 that may aid in repelling moisture from the copper surface. The process results in CHRCP 138. CHRCP 138 may have a structure similar to HRCP 900 in FIG. 8A (discussed below), where treated layer 904 may be black or grey, electrically insulating, passivating, has low reflectance, and thickness 906 is self-limited during the formation as the alkyl micelle is in near-perfect shape. The self-limitation of the thickness may be because the thickness of the CHRCP pattern can only be as thick as the conductive material deposited during plating. It is also understood that the characterization of a material as passivating may refer to the ability of a material to reduce or eliminate the degradation of another material, where degradation may be any process by which a material loses its desirable characteristics.

FIG. 2 is an illustration of an embodiment of a method of colorization for an HRCP. A colorization or colorizing method may refer to any method in which a material is made to interact with a reactant to change said material's optical properties. In FIG. 2, HRCP 200 comprises a plurality of lines indicated by unreacted lines 200a. A reactant is applied to HRCP 200 at reactant station 204, the reaction between the HRCP and the reactant forms a reacting pattern 206 as indicated by the cross-hatched lines as compared to the unreacted lines 200a. A rinsing station 208 contains a rinsing fluid 210 to remove the reactant applied at reactant station 204, the removal of the rinsing pattern stops the reaction between the pattern and the reactant applied at reactant station 204. A rinsed pattern 212 represented by a plurality of circles in rinsed pattern 212 is formed after the rinsing fluid 210 is removed. The rinsed pattern is then dried at drying station 214 to remove rinsing fluid 210 from the rinsed pattern 212, thereby forming high resolution conducting pattern with modified optical properties 216. It is appreciated that the differences in shading between at least 200a, 206, and 212 is representative of the changing of the pattern from an HRCP 200a to a reacted pattern 206 to a rinsed pattern 212 where the reaction was halted by the rinse. The rinse may be performed by any method in which a rinsing liquid may be applied to a material, including dipping or spraying (not pictured). The rinse is applied to halt or reduce the interaction (i.e. limit the reaction) between a reactant and said material in order to form a treated layer within a range of thickness or a target resistivity as shown in FIGS. 8A and 8B. As discussed in FIG. 1C and FIG. 9, in some embodiments a remover may be applied at a remover station (not pictured) to remove the reactant.

In an embodiment, reactant 204 is applied using a dip bath comprising triethanolamine sodium selenosulphate (Na₂SeSO₃) in an aqueous alkaline medium at 5° C. In the embodiment, vat 208 is an immersion rinse, and the rinsing fluid 210 is deionized water, dried 214 using an apparatus that blows heated air. The process results in CHRCP 216.

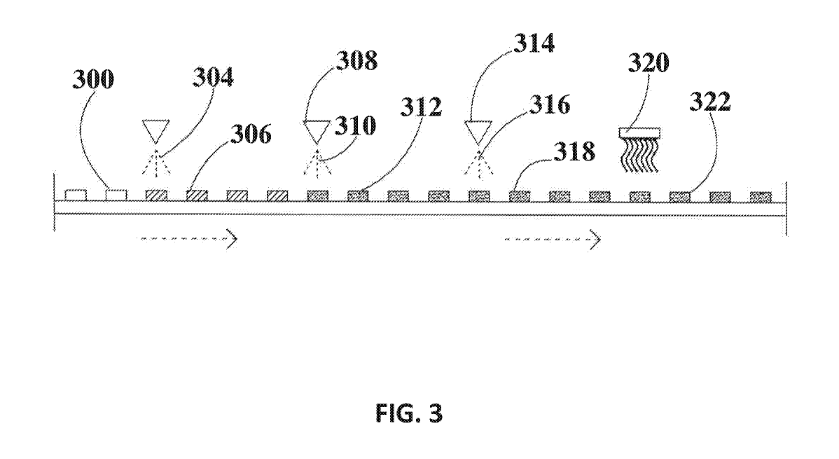

FIG. 3 is an alternate embodiment an HRCP colorization method. The method of colorizing HRCP 300 may comprise applying a reactant at reactant station 304 to HRCP 300 to form a reacting pattern 306. A rinse station 308 then removes the reactant applied at reactant station 304 from the reacting pattern 306 using rinsing fluid 310, thereby forming rinsed pattern 312. A rinse station 314 then applies rinsing fluid 316 on rinsed pattern 312 to form a twice-rinsed pattern 318. The twice-rinsed pattern is then dried at drying station 320 to remove any remnants of rinsing fluid 316 and rinsing fluid 310 from the twice-rinsed pattern 318, forming CHRCP 322. It is appreciated that while the cross-sectional geometry pictured in FIG. 3 has a rectangular geometry, the cross-sectional geometry may also be a square, triangle, trapezoid, etc.

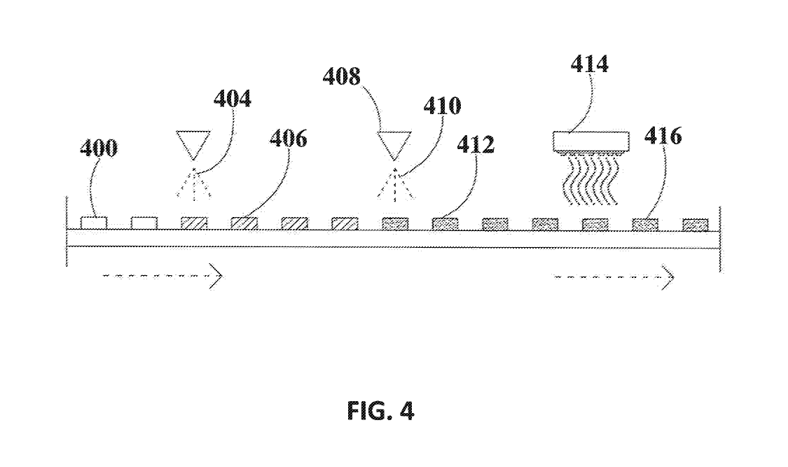

FIG. 4 is an embodiment of a method of a colorization for an HRCP. A reactant is applied 404 on HRCP 400, forming reacting pattern 406. A rinse may then be applied at rinse station 408 to remove the reactant 404 from reacting pattern 406 and stop the reaction, thereby forming a rinsed pattern 412. The rinsed pattern 412 is dried at drying station 414 to remove the rinsing fluid 410 which forms CHRCP 416. The reactant may be left on for a specific reaction time, where the reaction time is the length of time a reactant interacts with a material. The reaction time may impact the thickness and resultant properties of the patterned substrate.

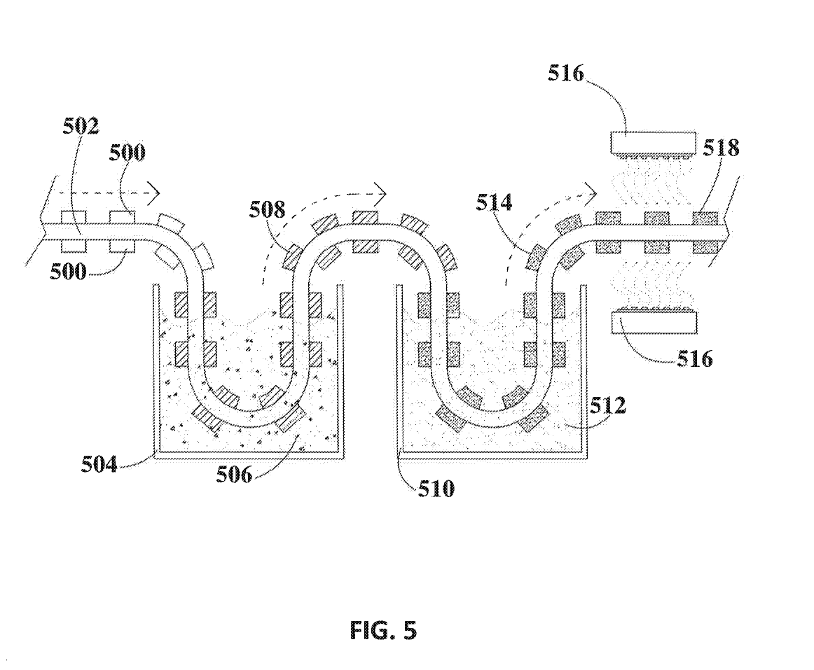

FIG. 5 is an alternate embodiment of a method of colorization of an HRCP. In this embodiment, HRCP 500 is present on both sides of substrate 502. A reactant is applied to HRCP 500 at reactant station 506, forming reacting pattern 508. A rinse may be applied at rinse station 510 to remove the reactant applied at reactant station 506 from the reacting pattern 508 using rinsing fluid at rinsing station 512, thereby forming rinsed pattern 514. The rinsed pattern 514 may then be dried at drying station 516 to remove the rinsing fluid applied at rinsing station 512 from the rinsed pattern 514, thus forming CHRCP 518. In some embodiments, the drying station 512 may comprise a plurality of driers that may be positioned on opposite sides of the substrate.

FIG. 6 is an illustration of an embodiment of an HRCP. In this example, HRCP 600 comprises a non-colorized conductive material 604, for example, copper disposed on substrate 602. Prior to colorization and modification of the optical properties, the plurality of conductive lines 604 may be shiny and metallic, the exact optical properties being determined by the metal or alloy used to form the conductive lines 604. This may mean that the substrate 602, when assembled into a touch screen display may still have, if not visible lines since the lines may be microscopic measuring from 1 micron-50 microns, then a general reflection from the screen because of these reflective lines. Therefore, it may be preferable to modify the optical properties after the conductive material is deposited to form the plurality of conductive lines 604 so that this sort of glare is lessened.

FIG. 7 is an illustration of an HRCP 700 with modified optical properties which may also be referred to as colorized or blackened. The reacted copper material 704 is disposed on substrate 602. The properties may be modified by the methods disclosed herein.

FIGS. 8A-8B are illustrations of embodiments of cross-sectional geometries of lines from HRCPs. A HRCP may comprise a plurality of lines with varying cross-sectional geometries including square, rectangle, half-circle, triangle, and trapezoid. FIG. 8A shows an example of an HRCP line 900 and FIG. 8B shows an example of an HRCP line 908. FIG. 8A is an example of a half-circle shaped line, and FIG. 8B is an example of a line with a rectangular cross section. In FIG. 8A, HRCP line 900 comprises treated layer 904 which extends around the outer surface of the untreated material 902. FIG. 8B comprises treated layer 912 which extends around the outer surface of untreated material 910. Layers 904 and 912 are reacted layers which means that the ink pattern has interacted with a reactant, not shown, and reacted to form a colorized compound of layer thickness 906 and layer thickness 914, respectively. Untreated material 902 in FIG. 8A and untreated material 910 in FIG. 8B show portions of the lines that have not interacted with a reactant. In some embodiments, the cross-sectional geometries of the plurality of the lines are the same, and in some embodiments the plurality of lines may comprise two or more different cross-sectional geometries, or varying dimensions of the same cross-sectional geometry.

Treated layer 904 may be black, electrically conductive, passivating, and have a low reflectance, and layer thickness 906 between 25 nm and 5000 nm. In an alternate embodiment, treated layer 904 is a monolayer that is black, electrically insulating, passivating, and has a low reflectance. A low reflectance of copper is about 60% reflecting which is very visible, silver may have a reflectance of 80-90% but the change in optical properties makes is <20%.

Turning to FIGS. 2 and 8A, CHRCP 216 may have a treated layer 904 comprised of CuSO₄ and the layer may be black, electrically conductive, passivating, and have a low gloss. The layer thickness 906 may be between 25 nm and 5000 nm. In an alternate embodiment, treated layer 904 is gray, electrically insulating, passivating, and has low reflectance.

Turning to FIGS. 5 and 8A, in an alternate embodiment, the reactant 506 is Novacan Black Patina, the rinse 510 is an immersion rinse, the rinsing fluid 512 is deionized water, and the drying 516 is performed by an apparatus that blows heated air. In this embodiment (not pictured), substrate 502 has an HRCP 500 on more than one side of substrate 502. The HRCP may be the same on the first side and the second side or, alternatively, the HRCP on the first side may be different than the HRCP on the second side. The process results in CHRCP 518 which may have a structure similar to HRCP 900 in FIG. 8A, where treated layer 904 is black, electrically conductive, passivating, has low gloss, and a thickness 906 between 25 nm and 5000 nm. In this example, HRCP 518 is a pattern of lines with a width of 50 μm that are 500-900 nm thick and 5 to 12 cm long. In one example, the HRCP 518 is a pattern of lines 50 μm wide and the resistivity (ρ) may be from 3.6 m.ohm-cm-4.8 m.ohm-cm. In another example, the resistivity (ρ) is increased during the colorization process by 23.2%-60.4%.

FIG. 9 is an illustration of an embodiment of a method for manufacturing an HRCP and altering the optical properties of that pattern. Substrate 1000 is disposed on an unwind roll 1002 and is transferred from the unwind roll 1002 to a first cleaning station 1004 via, for example, any known roll to roll handling method. The alignment of the substrate 1000 may be controlled with alignment mechanism 1006. The first cleaning station 1004 may then be used to remove impurities (not pictured) from substrate 1000.

Substrate 1000 may pass through a second cleaning station 1008. The cleaning process may be performed by a method or apparatus by which impurities or contaminants may be removed from a material surface. Substrate 1000 may then undergo a first printing at first printing station 1010, where a microscopic pattern, not shown, is applied on at least one side of substrate 1000 in a process that may involve at least one master plate 1012 and at least one ink, not shown. The quantity of ink applied to substrate 1000 may be regulated by a metering device, not shown, and may depend on the speed of the process, ink characteristics, and pattern characteristics. First printing process 1010 may be followed by one or more curing process at first curing station 1014.

Substrate 1000 may undergo a second printing process 1016. In the second printing process 1016 a master plate 1018 is used to apply an ink, not shown, onto at least one side of substrate 1000. The quantity of ink applied to substrate 1000 may be regulated by a metering device, not shown, and may depend on the speed of the process, ink characteristics, and pattern characteristics. Second printing process 1016 may be followed by at least one curing process at second curing station 1020. The substrate 1000 may then be subjected to plating at a first plating station 1022, which may be followed by a first rinse 1024 utilizing rinsing fluid 1026. The substrate 1000 may be dried at drying station 1028, thereby forming a high resolution conducting pattern 1030 on substrate 1000. A mask (not pictured) may be applied to portions of HRCP 1030. The reactant may be applied at mask application station 1038 to HRCP 1030, which may be followed by a second rinse at rinse station 1040. The second rinse at rinse station 1040 may use rinsing fluid 1042 to remove reactant 1038 from HRCP 1030, and may be followed by drying at first drying station 1044. In an embodiment, a remover may then be applied to HRCP 1030 at remover application station 1048. A third rinse at rinsing station 1050 may utilizing rinsing fluid 1052 to remove the remover 1048 from HRCP 1030. Drying at second drying station 1054 may then follow, resulting in the formation of CHRCP 1056. Substrate 1000 may then be collected on a winding roll 1058.

In an alternate embodiment, substrate 1000 is a thin, transparent, flexible, dielectric substance, alignment mechanism 1006 is an alignment cable, first cleaning system 1004 is a high electric field ozone generator, and a second cleaning system 1008 is a web cleaner. In this embodiment, the first printing process 1010 prints on only one side of substrate 1000 and the ink used in first printing process 1010 and second printing process 1016 contains plating catalysts. The substrate 1000 may undergo a first curing at curing station 1014 and a second curing at curing station 1020. Each curing process may comprise an ultraviolet (UV) curing apparatus and a heating oven. Plating process 1022 may be an electroless plating carried out in a plating tank that contains copper or other conductive material in a liquid state at a temperature range between 20° C. and 90° C. In this example, each of the plurality of lines in HRCP 1030 may have a line width that is less than 5 microns. The resultant CHRCP 1056 is considered transparent, as the human eye is unable to perceive the pattern on the transparent substrate. It is noted that, in contrast to a CHRCP 1056 with a pattern of 5-micron-wide lines that may be considered transparent, a CHRCP 1056 with a pattern of 20-micron-wide lines may not be considered transparent. The pattern is black and has low gloss so that it reflects little light from all angles. Additionally, the portions of CHRCP 1056 that are to be bonded to an electronic apparatus have the requisite properties to undergo bonding. The properties required to undergo bonding are those such as conductivity and peel strength. The grids give invisibility and conductivity to the pattern and protect the pattern from acidic atmospheric affects like temperature and humidity while providing good bond strength to be flexible.

In an alternate embodiment, substrate 1000 may be a thin, transparent, flexible, dielectric substance. The alignment mechanism 1006 is an alignment cable, the first cleaning system 1004 is a high electric field ozone generator, and the second cleaning system 1008 is a web cleaner. In this embodiment, the first printing process 1010 prints on only one side of substrate 1000, the ink used in first printing process 1010 and second printing process 1016 contains plating catalysts. In the embodiment, first curing at first curing station 1014 and second curing at second curing station 1020 each comprise an UV curing apparatus and a heating oven. Plating process 1022 may be an electroless plating carried out in a plating tank that contains copper or other conductive material in a liquid state at a temperature range between 20° C. and 90° C. In this example, HRCP 1030 has a line width of approximately 20 microns.

### Experimental Results

In a set of experiments, the reaction time between the reactant and HRCP was varied to observe the resultant layer thickness. It is noted that, in contrast to a CHRCP 1056 with a pattern of 5-micron-wide lines that may be considered transparent, a CHRCP 1056 with a pattern of 20-micron-wide lines may not be considered transparent.

TABLE 1

| Reaction Time, sec | Thickness 906, μm |
|---|---|
| 0 | 2.45 |
| 10 | 2.60 |
| 20 | 2.90 |
| 30 | 3.9 |

Table 1 above provides values for the reaction when carried out at room temperature. Alternatively, at higher temperatures, the reaction time may shorten as the reaction may be accelerated at higher temperatures. In some embodiments, as the reaction time is increased, thickness 906 increases, and the adhesion strength and quality of the surface will be affected. In addition, the resistivity of lines before and after colorization was measured and it was found that the resistivity of a line increased from 23.2%-60.4% to after the optical properties were modified.

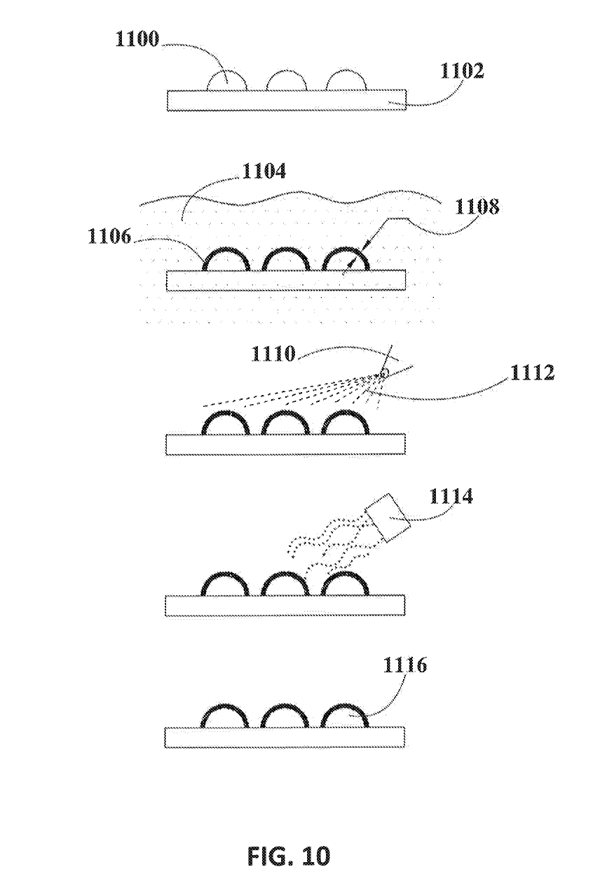

FIG. 10 is an illustration of an exploded view of a cross-section of a substrate undergoing a change to the optical properties of an HRCP. In FIG. 10, HRCP 1100 is formed on substrate 1102 and colorized in a method comprising at least 3 steps. Reactant 1104 is applied on HRCP 1100. The areas of High Resolution Conducting Pattern exposed to reactant 1104 then react with it to form colorized layer 1106, with thickness 1108. Rinse 1110 is then used to apply rinsing fluid 1112, removing reactant 1104. The rinsed substrate 1102 may then be dried 1114 to remove the remaining rinsing fluid 1112, leaving CHRCP 1116.

Preferably, HRCP 1100 comprises a plurality of copper lines printed on a substrate 1102 wherein the substrate may be glass, paper, poly(ethylene terephthalate) (PET) and or poly(methyl methacrylate) PMMA. Reactant 1104 is applied to HRCP 1100 to form the reacted pattern (coating) indicated by its thickness 1108. In this example, reactant 1104 is an aqueous solution of 7-15% Nitric Acid (HNO₃), 0.5-3% Selenium Dioxide (SeO₂), and 3-10% Copper Sulfate (CuSO₄) by weight, and is at room temperature. The interaction between reactant 1104 and HRCP 1100 leads to the formation of colorized layer 1106, which is mainly a copper selenium compound (Cu₂Se) that is black in color, has low gloss, and has passivating properties. Thickness 1108 is a function of the reaction's completeness and may depend on the reaction time. The reaction is stopped by rinse 1110, a spray nozzle, which applies rinsing fluid 1112, deionized water, to remove reactant 1104. The substrate may be dried 1114, using an air knife to remove rinsing fluid 1112 remnants, resulting in CHRCP 1116.

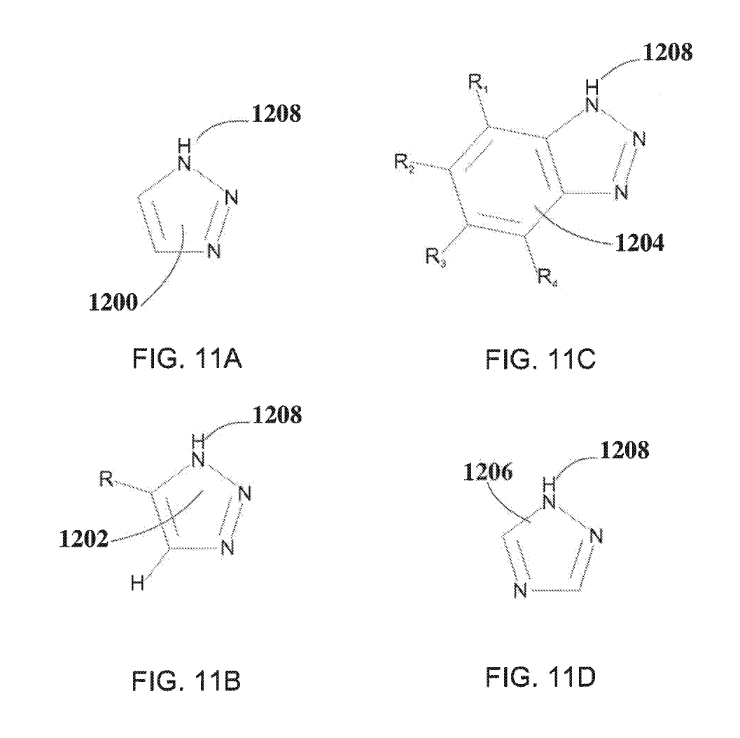

In an alternate embodiment, the reactant may be from the triazole family. FIGS. 11A-11D shows formulas for various triazole compounds. FIG. 11A is an illustration of the molecular composition of 1,2,3-Triazole 1200. FIG. 11B is an illustration of the molecular composition of alkyltriazole 1202, and FIG. 11C is an illustration of the molecular composition of alkyltriazole 1204. FIG. 11D is an illustration of the molecular composition of 1,2,4 Triazole 1206 (FIG. 12D). All four compounds depicted in FIGS. 11A-11D contain NH— Group 1208.

FIG. 12 is an illustration of an embodiment of a method for manufacturing a CHRCP. A high resolution conductive pattern (HRCP) is formed 1202 when a substrate is cleaned at a first cleaning station 1204 to remove impurities via, for example, any known roll to roll handling method. First cleaning station 1204 may comprise one or more cleaning processes depending on the embodiment. The substrate may then undergo a first printing at first printing station 1206, where a microscopic pattern, not shown, is applied on at least one side of the substrate in a process that may involve at least one master plate and at least one ink, not shown. The type of ink used may depend on the plating process described below or on the shape and dimensions of the printed pattern. The quantity of ink applied to substrate may be regulated by a metering device, not shown, and may depend on the speed of the process, ink characteristics, and pattern characteristics. The first printing process 1206 may be followed by curing station 1208 which may comprise one or more curing operations.

The substrate may then undergo a second printing at printing station 1210. In the second printing process 1210 a master plate is used to apply an ink, onto at least one side of the substrate. The quantity of ink applied to the substrate may be regulated by a metering device, not shown, and may depend on the speed of the process, ink characteristics, and pattern characteristics. Second printing at printing station 1210 may be followed by at least one curing process at curing station 1212. It is appreciated that the second printing at printing station 1210 may be (1) printing a pattern on the same side of the substrate as the first pattern was printed on at first printing station 1206 which may be adjacent to the first pattern, (2) printing a pattern on the opposite side of the first pattern on the same substrate, or (3) printing a pattern on a different substrate than the substrate that has the first printed pattern. It is appreciated that, regardless of where the second pattern is printed, the first and the second patterns may require assembly if they are not printed on the same side of a substrate, and that this assembly may take place after modifying the optical properties at 1222 as discussed below. In addition, the printing and plating processes may be done in series or in parallel with respect to the two patterns.

The substrate may then be subjected to plating at a plating station 1214, which may be followed by a first rinse 1216. It is appreciated that the plating station may comprise one or more plating modules and that the plating process may be run in series or in parallel, that is, the first pattern and the second pattern printed at 1206 and 1210 respectively may be plated after printing separately or may be plated simultaneously. The substrate may be dried at drying station 1218, thereby forming a high resolution conducting pattern 1220.

Once the HRCP is formed, the optical properties may be modified 1222. A mask (not pictured) may be applied to portions of HRCP 1220 at mask application station 1224. The reactant may be applied at reactant application station 1228, which may be followed by a second rinse at rinse station 1230. The reactant applied may be a SeO₂—CuSO₄-phosphoric acid solution, for example, 1-4 wt % SeO₂, 1.5-3 wt % CuSO₄, and 3 wt %-7 wt % phosphoric acid. In an alternate embodiment, the reactant applied may be a solution of HNO₃, SeO₂, and CuSO₄, for example, 7-15% Nitric Acid (HNO₃), 0.5-3% Selenium Dioxide (SeO₂), and 3-10% Copper Sulfate (CuSO₄), or the reactant is one of a triethanolamine sodium selenosulphate (Na₂SeSO₃) in an aqueous alkaline medium at 5° C. and a solution of potassium sulfide in ethanol;

The second rinse at rinse station 1230 may use a rinsing fluid such as deionized water, ethanol, or isopropyl alcohol to remove the reactant from HRCP 1220, and may be followed by drying at second drying station 1234. The rinse station may be an immersion rinse or a spray rinse depending on the embodiment. A remover such as dimethyl sulfoxide or acetone may then be applied to HRCP 1220 at remover application station 1236. In an alternate embodiment, a drying knife may be used to remove the reactant. It is appreciated that rinsing the reactant stops the reaction that creates the reacted layer in FIGS. 8A and 8B, but that the reactant may not be removed by the rinse so a third rinse at rinsing station 1240 may be utilized. The pattern may then be dried at drying station 1242, forming optically modified (colorized) pattern CHRCP.

While the above description contains many specificities, these should not be construed as limitations on the scope of the disclosure, but as exemplifications of the presently preferred embodiments thereof. Many other ramifications and variations are possible within the teachings of the disclosure. For example, any of the colorizing methods described in any of the figures may be adapted to work with any manufacturing process known in the art. Additionally, the methods disclosed herein may yield varied results depending on the process parameters controlled; i.e. the thickness of the colorized layer may vary by prolonging or shortening the time that the reactant interacts with the high resolution conducting pattern; the reaction completeness may depend on the reaction time as well as the temperature at which the reaction is carried out. In many cases, these methods may be combined and modified to form other methods for colorizing the high resolution conducting patterns: drying methods may be omitted, rinsing steps may be added, reactants used may be varied (which may in turn lead to variations in the optical and electrical properties of the colorized layer). The methods disclosed herein may also be adapted for applications in which additional sides of the substrates have high resolution conducting patterns in need of treatment. The manufacturing method for producing the high resolution conducting patterns to be colorized need not be the one exemplified in the description, and all of the components previous to the colorization method may be varied according to the desire of the manufacturer. The masking materials used in the manufacturing may vary, as well as the remover used to remove the masking material. The methods for applying said masks may also include additional steps, especially if the masking material requires curing or if additional control over the application area is desired. The cross-sectional geometries of the high resolution conducting patterns may also vary according to the manufacturing method employed. The manufacturing method may also be such that a HRCP may be applied and may be colorized on one side of the substrate and subsequently another HRCP may be applied and may be colorized on the same or on additional sides of the substrate.

The embodiments disclosed herein may, in the alternative, comprise processing methods and apparatuses such as Sol gel coating, slot dye coating, physical vapor deposition, chemical vapor deposition, sputter deposition, chemical baths, and electrophoretic deposition.

Applications for the disclosure may also include applications in Super ionic conductors, Photo-detectors, Photothermal conversion, Electroconductive electrodes, Microwave shielding coating, and the Solar Energy Industry without being limited to said areas. There may additionally be applications in which the conductive or optical properties of copper selenium compounds, formed on copper by reactants may be of use on materials other than high resolution conducting patterns.

Although the disclosure has been described with reference to particular embodiments, it should be understood that these embodiments are merely illustrative of the principles and applications of the present disclosure. It also should be understood that numerous modifications may be made to these illustrative embodiments without departing from the spirit and scope of the present disclosure as defined by the following claims.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A method of changing the optical properties of a high resolution conductive pattern comprising:
printing a first microscopic pattern on a first side of a substrate using an ink comprising a plating catalyst;
curing the substrate;
printing a second microscopic pattern using the ink;
plating the substrate, wherein plating the substrate comprising electroless plating, to form a high resolution conductive pattern (HRCP) on the substrate;
disposing, on the substrate, a reactant, to form a reacting pattern comprising a reacted layer, wherein the reacted layer thickness is between 25 nm-5000 nm; and
rinsing the substrate.

2. The method of claim 1, wherein the electroless plating comprises disposing at least a portion of the substrate in a plating tank comprising a conductive material in a liquid state to form a high resolution conductive pattern.

3. The method of claim 2, wherein the conductive material is one of copper (Cu), silver (Ag), gold (Au), nickel (Ni), tin (Sn) and Palladium (Pd).

4. The method of claim 1, wherein the HRCP comprises a plurality of lines, and wherein each line width of the plurality of line widths is between 1-20 microns.

5. The method of claim 1, wherein the HRCP comprises a plurality of lines, and wherein each line width of the plurality of lines is between 2-5 microns.

6. The method of claim 1, wherein the substrate comprising the first microscopic pattern is a first substrate, wherein the second microscopic pattern is printed on one of the first side of the first substrate adjacent to the first pattern, a second side of the first substrate, or on a second substrate, wherein the second substrate is different from the first substrate.

7. The method of claim 1 wherein the substrate is one of a flexible polymer, paper, or glass.

8. The method of claim 1 further comprising disposing a mask on at least part of the HRCP, forming a masked portion and an unmasked portion of the HRCP, and disposing, on the unmasked portion, a reactant, forming a reacting pattern comprising a reacted layer.

9. The method of claim 1, wherein the reactant comprises SeO₂, CuSO₄, and phosphoric acid.

10. The method of claim 9, wherein the reactant comprises 1-4 wt % SeO₂, 1.5-3 wt % CuSO₄, and 3 wt %-7 wt % phosphoric acid.

11. The method of claim 1, wherein disposing the reactant comprises immersing the substrate in a tank of reactant.

12. The method of claim 9, wherein the reactant is removed by dimethyl sulfoxide.

13. The method of claim 9, wherein rinsing the substrate comprises rinsing the substrate in one of isopropyl alcohol and deionized water.

14. The method of claim 1 wherein the reactant comprises HNO₃, SeO₂, and CuSO₄.

15. The method of claim 14 wherein the reactant comprises 7-15% Nitric Acid (HNO₃), 0.5-3% Selenium Dioxide (SeO₂), and 3-10% Copper Sulfate (CuSO₄).

16. The method of claim 14, further comprising removing the reactant from the substrate using dimethyl sulfoxide.

17. The method of claim 8, wherein disposing the mask, disposing the reactant, are performed by one of a spray station or a spin coating stations.

18. The method of claim 1, further comprising removing the reactant, wherein removing the reactant is performed by one of a spray station or a spin coating stations.

19. The method of claim 1, wherein the reactant is a triethanolamine sodium selenosulphate (Na2SeSO3) in an aqueous alkaline medium at 5° C., and wherein rinsing the substrate comprises rinsing the substrate using an immersion rinse and deionized water.

20. The method of claim 1, wherein the reactant is a solution of potassium sulfide and ethanol, and wherein rinsing the substrate comprises rinsing the substrate using an immersion rinse and ethanol.

21. A method of changing the optical properties of a high resolution conductive pattern comprising:
printing a first microscopic pattern on a first side of a substrate using an ink comprising a plating catalyst;
curing the first substrate;
printing a second microscopic pattern using the ink;
plating the substrate, wherein plating the substrate comprising electroless plating, to form a high resolution conductive pattern (HRCP) on the substrate;
disposing, on the substrate, a reactant, to form a reacting pattern comprising a reacted layer, wherein the reacted layer thickness is between 25 nm-5000 nm, and wherein the reactant comprises SeO₂, CuSO₄, and phosphoric acid; and
rinsing the substrate in one of in one of isopropyl alcohol and deionized water.

22. The method of claim 21, wherein the electroless plating comprises disposing at least part of the substrate in a plating tank comprising a conductive material in a liquid state to form a high resolution conductive pattern.

23. The method of claim 22, wherein the conductive material is one of copper (Cu), silver (Ag), gold (Au), nickel (Ni), tin (Sn) and Palladium (Pd).

24. The method of claim 21, wherein the HRCP comprises a plurality of lines, and wherein a line width of the plurality of line widths is between 1-20 microns.

25. The method of claim 21, wherein the HRCP comprises a plurality of lines, and wherein each line width of the plurality of lines is between 2-5 microns.

26. The method of claim 21, wherein the substrate comprising the first microscopic pattern is a first substrate, wherein the second microscopic pattern is printed on one of the first side of the first substrate adjacent to the first pattern, a second side of the first substrate, or on a second substrate, wherein the second substrate is different from the first substrate.

27. The method of claim 21, wherein the reactant comprises 1-4 wt % SeO₂, 1.5-3 wt % CuSO₄, and 3 wt %-7 wt % phosphoric acid.

28. The method of claim 21, wherein disposing the reactant comprises immersing the substrate in a tank of reactant.

29. The method of claim 21, wherein the reactant is removed by dimethyl sulfoxide.

30. The method of claim 21, further comprising removing the reactant, wherein removing the reactant is performed by one of a spray station or a spin coating stations.
